(19) United States
(12) Patent Application Publication
(10) Pub. No.: US 2026/0190227 A1
(43) Pub. Date: Jul. 2, 2026

(54) SUBSTRATE STRUCTURE

(71) Applicant: Unimicron Technology Corp., Taoyuan City (TW)

(72) Inventors: Tzyy-Jang Tseng, Taoyuan City (TW); Chin-Sheng Wang, Taoyuan City (TW); Ra-Min Tain, Hsinchu County (TW); Guang-Hwa Ma, Hsinchu City (TW)

(73) Assignee: Unimicron Technology Corp., Taoyuan City (TW)

(21) Appl. No.: 19/183,947

(22) Filed: Apr. 21, 2025

Related U.S. Application Data
(60) Provisional application No. 63/739,681, filed on Dec. 30, 2024.

(30) Foreign Application Priority Data
Mar. 4, 2025 (TW) 114107983

(51) Int. Cl. H05K 1/11

(52) U.S. Cl. CPC H05K 1/115; H05K 2201/0191; H05K 2201/068; H05K 2201/096; H05K 2201/09636

(57) ABSTRACT

A substrate structure includes a base and at least one build-up structure layer. The base includes a dielectric core plate and at least one first conductive through hole penetrating the dielectric core plate. The at least one build-up structure layer is disposed on the base and includes a dielectric layer and at least one second conductive through hole penetrating the dielectric layer. A coefficient of thermal expansion of the dielectric layer is less than a coefficient of thermal expansion of the dielectric core plate. The at least one second conductive through hole is electrically connected to the at least one first conductive through hole.

### CROSS-REFERENCE TO RELATED APPLICATION

This application claims the priority benefits of U.S. provisional application Ser. No. 63/739,681, filed on Dec. 30, 2024, and Taiwan application serial no. 114107983, filed on Mar. 4, 2025. The entirety of each of the above-mentioned patent applications is hereby incorporated by reference herein.

### BACKGROUND

### Technical Field

The disclosure relates to a substrate structure, and more particularly, relates to a substrate structure exhibiting improved structural reliability.

### Description of Related Art

High-end integrated circuit (IC) carriers and circuit boards are becoming larger and thicker with lower manufacturing yields and increasingly severe board warping. To solve the board warping problem, the inner core plate needs to be thickened to increase structural support. However, this method causes the diameter and spacing of conductive through holes to increase, resulting in lower density of the conductive through holes, which is disadvantageous for high-end product applications. Further, when a glass substrate is used as the core layer, the thickness of the core plate is typically greater than 0.5 mm, while the diameter of conductive through holes is less than 0.1 mm, so the electroplating hole filling yield is low. In addition, the build-up structure on the core layer, due to its coefficient of thermal expansion being greater than that of the core layer, will generate tensile stress after heating processes (such as curing), which may easily cause the core layer made of glass to tear from the middle, and the structural reliability of the product is thereby reduced.

### SUMMARY

The disclosure provides a substrate structure exhibiting improved structural reliability.

The disclosure provides a substrate structure including a base and at least one build-up structure layer. The base includes a dielectric core plate and at least one first conductive through hole penetrating the dielectric core plate. The at least one build-up structure layer is disposed on the base and includes a dielectric layer and at least one second conductive through hole penetrating the dielectric layer. A coefficient of thermal expansion of the dielectric layer is less than a coefficient of thermal expansion of the dielectric core plate. The at least one second conductive through hole is electrically connected to the at least one first conductive through hole.

In an embodiment of the disclosure, the substrate structure further includes at least one bonding layer and at least one third conductive through hole. The at least one bonding layer is disposed between the base and the at least one build-up structure layer. The at least one third conductive through hole penetrates the at least one bonding layer and is electrically connected to the at least one first conductive through hole and the at least one second conductive through hole.

In an embodiment of the disclosure, a material of the at least one third conductive through hole includes conductive paste, metal slurry, or nanowires.

In an embodiment of the disclosure, in a cross-sectional view, the at least one first conductive through hole, the at least one second conductive through hole, and the at least one third conductive through hole have a same diameter.

In an embodiment of the disclosure, in a cross-sectional view, the at least one first conductive through hole, the at least one second conductive through hole, and the at least one third conductive through hole are aligned with one another.

In an embodiment of the disclosure, a material of the dielectric core plate of the base includes an organic material, an inorganic material, or a non-conductive composite material.

In an embodiment of the disclosure, a material of the dielectric layer of the at least one build-up structure layer includes an organic material, an inorganic material, or a non-conductive composite material.

In an embodiment of the disclosure, a material of the dielectric core plate of the base is the same as a material of the dielectric layer of the at least one build-up structure layer.

In an embodiment of the disclosure, a Young's modulus of the at least one build-up structure layer is larger than a Young's modulus of the base.

In an embodiment of the disclosure, a thickness of the base is between 80 micrometers and 800 micrometers.

In an embodiment of the disclosure, a thickness of the at least one build-up structure layer is between 80 micrometers and 800 micrometers.

In an embodiment of the disclosure, the base further includes at least one first circuit pattern, and the at least one build-up structure layer further includes at least one second circuit pattern. The at least one first circuit pattern is electrically connected to the at least one first conductive through hole. The at least one second circuit pattern is electrically connected to the at least one second conductive through hole.

To sum up, in the substrate structure provided by the disclosure, since the coefficient of thermal expansion of the dielectric layer of the build-up structure layer is less than the coefficient of thermal expansion of the dielectric core plate of the base, compressive stress is formed to inhibit warping of the substrate structure. As such, the substrate structure of the disclosure exhibits improved structural reliability.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a cross-sectional schematic view of a substrate structure according to an embodiment of the disclosure.

FIG. 2 is a cross-sectional schematic view of a substrate structure according to another embodiment of the disclosure.

FIG. 3 is a cross-sectional schematic view of a substrate structure according to another embodiment of the disclosure.

### DESCRIPTION OF THE EMBODIMENTS

The embodiments of the disclosure can be understood together with the drawings, and the drawings of the disclosure are also considered as part of the disclosure. It should be understood that the drawings of the disclosure are not drawn to scale. In fact, the dimensions of the components may be arbitrarily enlarged or reduced to clearly illustrate the features of the disclosure.

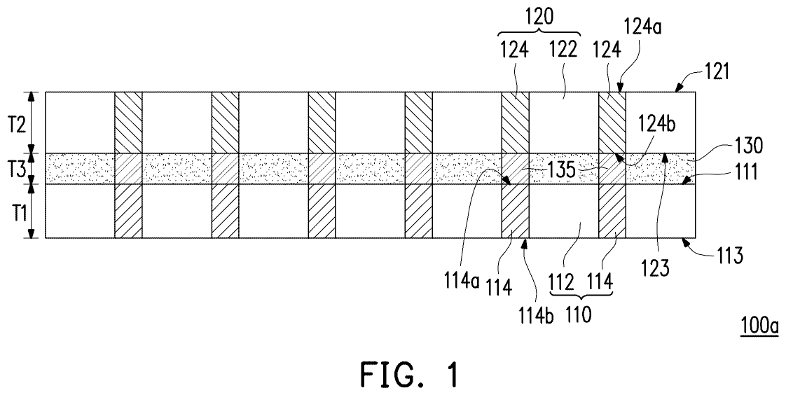

FIG. 1 is a cross-sectional schematic view of a substrate structure according to an embodiment of the disclosure. Referring to FIG. 1, in this embodiment, a substrate structure 100a includes a base 110 and at least one build-up structure layer (illustratively depicted as one build-up structure layer 120). The base 110 includes a dielectric core plate 112 and at least one first conductive through hole (illustratively depicted as a plurality of first conductive through holes 114) penetrating the dielectric core plate 112. The build-up structure layer 120 is disposed on the base 110 and includes a dielectric layer 122 and at least one second conductive through hole (illustratively depicted as a plurality of second conductive through holes 124) penetrating the dielectric layer 122. A coefficient of thermal expansion of the dielectric layer 122 is less than a coefficient of thermal expansion of the dielectric core plate 112. The second conductive through hole 124 is electrically connected to the first conductive through hole 114.

In detail, in this embodiment, the dielectric core plate 112 of the base 110 has a first surface 111 and a second surface 113 opposite to the first surface 111. The first conductive through hole 114 penetrates the dielectric core plate 112, that is, a periphery of the first conductive through hole 114 is encapsulated by the dielectric core plate 112. In an embodiment, in the first conductive through hole 114, a first end 114a and a second end 114b opposite to each other may be flush with the first surface 111 and the second surface 113 of the dielectric core plate 112, respectively. In an embodiment, in the first conductive through hole 114, the first end 114a and the second end 114b opposite to each other may be slightly higher than the first surface 111 and the second surface 113 of the dielectric core plate 112, respectively. In an embodiment, a thickness T1 of the base 110 may be, for example, between 80 micrometers and 800 micrometers. In an embodiment, a material of the dielectric core plate 112 of the base 110 may be, for example, an organic material, an inorganic material, or a non-conductive composite material. In an embodiment, the abovementioned organic material may be, for example, glass fiber resin (such as FR4), prepreg (PP), or an inorganic filler mixed in optical resistive resin, but it is not limited thereto. In an embodiment, the abovementioned inorganic material may be, for example, glass, ceramic, or glass ceramic. In an embodiment, the first conductive through hole 114 may be formed in the dielectric core plate 112 by means of electroplating, electroplating plus filling with metal slurry, or electroplating plus filling with non-conductive resin, but it is not limited thereto.

Referring to FIG. 1 again, in this embodiment, the dielectric layer 122 of the build-up structure layer 120 has an outer surface 121 and an inner surface 123 opposite to the outer surface 121, where the inner surface 123 is located between the outer surface 121 and the base 110. The second conductive through hole 124 penetrates the dielectric layer 122, that is, a periphery of the second conductive through hole 124 is encapsulated by the dielectric layer 122. In an embodiment, in the second conductive through hole 124, a first end 124a and a second end 124b opposite to each other may be flush with the outer surface 121 and the inner surface 123 of the build-up structure layer 120, respectively. In an embodiment, in the second conductive through hole 124, the first end 124a and the second end 124b opposite to each other may be slightly higher than the outer surface 121 and the inner surface 123 of the dielectric layer 122, respectively. In an embodiment, a thickness T2 of the build-up structure layer 120 may be, for example, between 80 micrometers and 800 micrometers. In an embodiment, a material of the dielectric layer 122 of the build-up structure layer 120 may be, for example, an organic material, an inorganic material, or a non-conductive composite material. In an embodiment, the abovementioned organic material may be, for example, glass fiber resin (such as FR4), prepreg (PP), or an inorganic filler mixed in optical resistive resin, but it is not limited thereto. In an embodiment, the abovementioned inorganic material may be, for example, glass, ceramic, or glass ceramic. In an embodiment, the second conductive through hole 124 may be formed in the dielectric layer 122 by means of electroplating, electroplating plus filling with metal slurry, or electroplating plus filling with non-conductive resin, but it is not limited thereto.

In an embodiment, the Young's modulus of the build-up structure layer 120 may be larger than a Young's modulus of the base 110. That is, the build-up structure layer 120 has the lowest coefficient of thermal expansion and largest Young's modulus compared to the base 110. In an embodiment, the material of the dielectric core plate 112 of the base 110 may be the same as the material of the dielectric layer 122 of the build-up structure layer 120, for example, both may be an organic material. In an embodiment, the material of the dielectric core plate 112 of the base 110 may be the same as the material of the dielectric layer 122 of the build-up structure layer 120, for example, both may be an inorganic material. In an embodiment, the material of the dielectric core plate 112 of the base 110 may be an organic material, while the material of the dielectric layer 122 of the build-up structure layer 120 may be an inorganic material. In an embodiment, the material of the dielectric core plate 112 of the base 110 may be an inorganic material, while the material of the dielectric layer 122 of the build-up structure layer 120 may be an organic material. In an embodiment, when the dielectric core plate 112 of the base 110 and/or the dielectric layer 122 of the build-up structure layer 120 use a glass material, density of the first conductive through hole 114 and/or the second conductive through hole 124 may increase. Further, because the glass surface is flat, it is also suitable for manufacturing high-density circuits thereon.

In addition, referring to FIG. 1 again, the substrate structure 100a of this embodiment also includes at least one bonding layer (illustratively depicted as one bonding layer 130) and at least one third conductive through hole (illustratively depicted as a plurality of third conductive through holes 135). The bonding layer 130 is disposed between the base 110 and the build-up structure layer 120, where the build-up structure layer 120 is fixed onto the base 110 through the bonding layer 130. The third conductive through hole 135 penetrates the bonding layer 130 and is electrically connected to the first conductive through hole 114 of the base 110 and the second conductive through hole 124 of the build-up structure layer 120. In an embodiment, in a cross-sectional view, the first conductive through hole 114, the second conductive through hole 124, and the third conductive through hole 135 may have a same diameter and are aligned in a straight line with one another. In other words, orthogonal projections of the first conductive through hole 114, the second conductive through hole 124, and the third conductive through hole 135 on a plane may completely overlap.

In an embodiment, a material of the bonding layer 130 may be, for example, a thermosetting or thermoplastic polymer material. In an embodiment, the material of the bonding layer 130 is, for example, polyimide (PI), ajinomoto build-up film (ABF), bismaleimide-triazine (BT), or other polymers. In an embodiment, a thickness T3 of the bonding layer 130 is, for example, 8 micrometers to 100 micrometers. In an embodiment, the bonding layer 130 has a low modulus and may act as a stress buffer layer. In an embodiment, a material of the third conductive through hole 135 formed in the bonding layer 130 is, for example, conductive paste (such as TLPS), metal slurry (such as copper slurry or silver slurry), or nanowires, but it is not limited thereto.

In brief, since the coefficient of thermal expansion of the dielectric layer 122 of the build-up structure layer 120 is less than the coefficient of thermal expansion of the dielectric core plate 112 of the base 110, compressive stress may be formed to inhibit warping of the substrate structure 100a. As such, the substrate structure 100a of this embodiment may exhibit improved structural reliability.

Other embodiments are described for illustration in the following. It should be noted that the reference numerals and a part of the contents in the previous embodiment are used in the following embodiments, in which identical reference numerals indicate identical or similar components, and repeated description of the same technical contents is omitted. Please refer to the description of the previous embodiments for the omitted content, which is not repeated hereinafter.

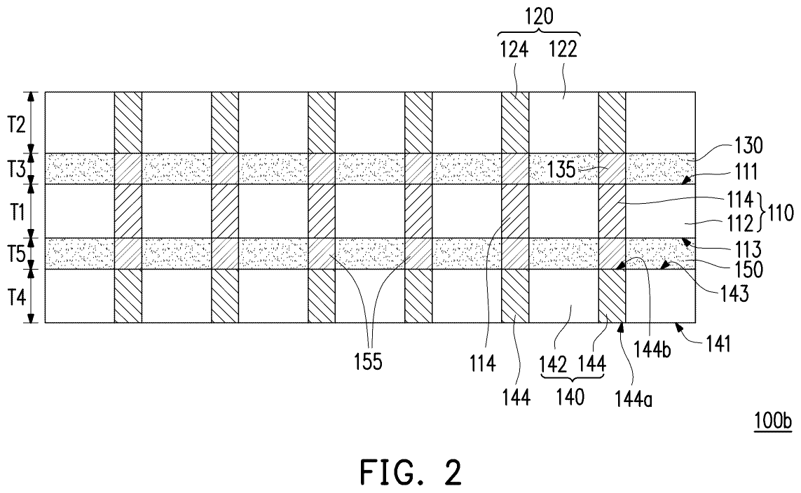

FIG. 2 is a cross-sectional schematic view of a substrate structure according to another embodiment of the disclosure. With reference to FIG. 1 and FIG. 2 together, a substrate structure 100b of this embodiment is similar to the substrate structure 100a, but the main differences therebetween are that in this embodiment, the substrate structure 100b further includes a build-up structure layer 140, a bonding layer 150, and a third conductive through hole 155. That is, the substrate structure 100b of this embodiment is formed by one base 110, two build-up structure layers 120 and 140, and two bonding layers 130 and 150.

In detail, the build-up structure layer 140 is disposed on the second surface 113 of the base 110. The build-up structure layer 140 includes a dielectric layer 142 and at least one second conductive through hole (illustratively depicted as a plurality of second conductive through holes 144) penetrating the dielectric layer 142. A coefficient of thermal expansion of the dielectric layer 142 is less than the coefficient of thermal expansion of the dielectric core plate 112. In this embodiment, the dielectric layer 142 of the build-up structure layer 140 has an outer surface 141 and an inner surface 143 opposite to the outer surface 141, where the inner surface 143 is located between the outer surface 141 and the base 110. The second conductive through hole 144 penetrates the dielectric layer 142, that is, a periphery of the second conductive through hole 144 is encapsulated by the dielectric layer 142. In an embodiment, in the second conductive through hole 144, a first end 144a and a second end 144b opposite to each other may be flush with the outer surface 141 and the inner surface 143 of the build-up structure layer 140, respectively. In an embodiment, in the second conductive through hole 144, the first end 144a and the second end 144b opposite to each other may be slightly higher than the outer surface 141 and the inner surface 143 of the dielectric layer 142, respectively. In an embodiment, a thickness T4 of the build-up structure layer 140 may be, for example, between 80 micrometers and 800 micrometers. In an embodiment, a material of the dielectric layer 142 of the build-up structure layer 140 may be, for example, an organic material, an inorganic material, or a non-conductive composite material. In an embodiment, the abovementioned organic material may be, for example, glass fiber resin (such as FR4), prepreg (PP), or an inorganic filler mixed in optical resistive resin, but it is not limited thereto. In an embodiment, the abovementioned inorganic material may be, for example, glass, ceramic, or glass ceramic. In an embodiment, the second conductive through hole 144 may be formed in the dielectric layer 142 by means of electroplating, electroplating plus filling with metal slurry, or electroplating plus filling with non-conductive resin, but it is not limited thereto.

In an embodiment, the material of the dielectric layer 122 of the build-up structure layer 120, the material of the dielectric core plate 112 of the base 110, and the material of the dielectric layer 142 of the build-up structure layer 140 may be a combination of glass, an organic material, and glass (GOG) in sequence. In an embodiment, the material of the dielectric layer 122 of the build-up structure layer 120, the material of the dielectric core plate 112 of the base 110, and the material of the dielectric layer 142 of the build-up structure layer 140 may be a combination of ceramic, an organic material, and ceramic (COC) in sequence. In an embodiment, the material of the dielectric layer 122 of the build-up structure layer 120, the material of the dielectric core plate 112 of the base 110, and the material of the dielectric layer 142 of the build-up structure layer 140 may be a combination of ceramic, an organic material, and glass (COG) in sequence. In an embodiment, the substrate structure 100b may be treated as a type of hybrid core structure.

It is worth mentioning that in a structure where an organic material (such as the dielectric core plate 112 of the base 110) is covered on both sides with two pieces of glass (such as the dielectric layers 122 and 142 of the build-up structure layers 120 and 140), the thickness of the organic material may be effectively reduced, and the rigidity may be increased. Further, since the thickness of the organic material may be reduced, smaller through holes may be used, a spacing may be reduced, and the density of the conductive through holes may be correspondingly increased.

In addition, referring to FIG. 2, the bonding layer 150 is disposed between the second surface 113 of base 110 and the build-up structure layer 140, where the build-up structure layer 140 is fixed onto the base 110 through the bonding layer 150. The third conductive through hole 155 penetrates the bonding layer 150 and is electrically connected to the first conductive through hole 114 of the base 110 and the second conductive through hole 144 of the build-up structure layer 140. In an embodiment, in a cross-sectional view, the first conductive through hole 114, the second conductive through hole 124, the second conductive through hole 144, the third conductive through hole 135, and the third conductive through hole 155 may have a same diameter and are aligned in a straight line with one another. In other words, orthogonal projections of the first conductive through hole 114, the second conductive through hole 124, the second conductive through hole 144, the third conductive through hole 135, and the third conductive through hole 155 on a plane may completely overlap.

In an embodiment, a material of the bonding layer 150 may be, for example, a thermosetting or thermoplastic polymer material. In an embodiment, the material of the bonding layer 150 is, for example, polyimide (PI), ajinomoto build-up film (ABF), bismaleimide-triazine (BT), or other polymers. In an embodiment, a thickness T5 of the bonding layer 150 is, for example, 8 micrometers to 100 micrometers. In an embodiment, the bonding layer 150 has a low modulus and may act as a stress buffer layer. In an embodiment, a material of the third conductive through hole 155 formed in the bonding layer 150 is, for example, conductive paste (such as TLPS), metal slurry (such as copper slurry or silver slurry), or nanowires, but it is not limited thereto.

In brief, in this embodiment, the outermost build-up structure layers 120 and 140 have the lower coefficient of thermal expansion and the larger Young's modulus values than those of the dielectric core plate 112 of the base 110. Since the coefficient of thermal expansion of the dielectric layers 122 and 142 of the build-up structure layers 120 and 140 is less than the coefficient of thermal expansion of the dielectric core plate 112 of the base 110, compressive stress may be formed to inhibit warping of the substrate structure 100b. As such, the substrate structure 100b of this embodiment may exhibit improved structural reliability.

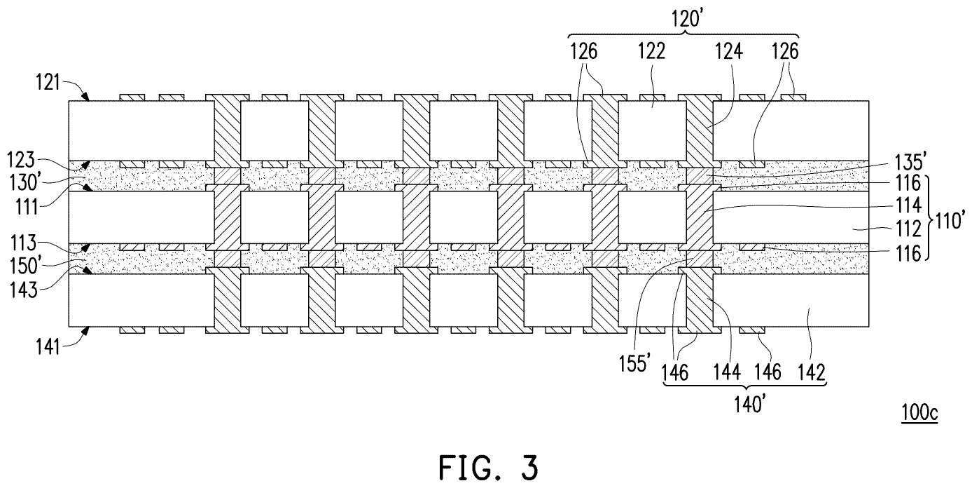

FIG. 3 is a cross-sectional schematic view of a substrate structure according to another embodiment of the disclosure. With reference to FIG. 2 and FIG. 3 together, a substrate structure 100c of this embodiment is similar to the substrate structure 100b, but the main differences therebetween are that in this embodiment, a base 110′ further includes at least one first circuit pattern 116, a build-up structure layer 120′ further includes at least one second circuit pattern 126, and a build-up structure layer 140′ further includes at least one second circuit pattern 146. The first circuit pattern 116 is disposed on the first surface 111 and the second surface 113 of the dielectric core plate 112, where the first circuit pattern 116 is electrically connected to the first conductive through hole 114. In an embodiment, the first circuit pattern 116 may be, for example, a pad, a circuit, a conductive blind hole, or a combination of the foregoing. The second circuit pattern 126 is disposed on the outer surface 121 and the inner surface 123 of the dielectric layer 122, where the second circuit pattern 126 is electrically connected to the second conductive through hole 124. In an embodiment, the second circuit pattern 126 may be, for example, a pad, a circuit, a conductive blind hole, or a combination of the foregoing. The second circuit pattern 146 is disposed on the outer surface 141 and the inner surface 143 of the dielectric layer 142, where the second circuit pattern 146 is electrically connected to the second conductive through hole 144. In an embodiment, the second circuit pattern 146 may be, for example, a pad, a circuit, a conductive blind hole, or a combination of the foregoing.

In addition, the build-up structure layer 120′ is fixed onto the first surface 111 of the base 110 through a bonding layer 130′. The bonding layer 130′ contacts and covers the inner surface 123 of the build-up structure layer 120′, part of the second circuit pattern 126, part of the first circuit pattern 116, and the first surface 111 of the dielectric core plate 112. The build-up structure layer 140′ is fixed onto the second surface 113 of the base 110 through a bonding layer 150′. The bonding layer 150′ contacts and covers the inner surface 143 of the build-up structure layer 140′, part of the second circuit pattern 146, part of the first circuit pattern 116, and the second surface 113 of the dielectric core plate 112. The second conductive through hole 124 is electrically connected to the first conductive through hole 114 through a third conductive through hole 135′, and the second conductive through hole 144 is electrically connected to the first conductive through hole 114 through a third conductive through hole 155′.

Since the base 110′ and the build-up structure layers 120′ and 140′ are bonded through the bonding layers 130′ and 150′, the base 110′ and the build-up structure layers 120′ and 140′ are separately wired during bonding, and wiring density of the substrate structure 100c is thus increased. In addition, in an embodiment that is not shown, a plurality of substrate structures may also be combined through an adhesive bonding layer and electrically connected to the substrate structure through conductive through holes in the bonding layer.

In view of the foregoing, in the substrate structure provided by the disclosure, since the coefficient of thermal expansion of the dielectric layer of the build-up structure layer is less than the coefficient of thermal expansion of the dielectric core plate of the base, compressive stress may be formed to inhibit warping of the substrate structure. As such, the substrate structure of the disclosure may exhibit improved structural reliability.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A substrate structure, comprising:
a base comprising a dielectric core plate and at least one first conductive through hole penetrating the dielectric core plate; and
at least one build-up structure layer disposed on the base and comprising a dielectric layer and at least one second conductive through hole penetrating the dielectric layer, wherein a coefficient of thermal expansion of the dielectric layer is less than a coefficient of thermal expansion of the dielectric core plate, and the at least one second conductive through hole is electrically connected to the at least one first conductive through hole.

2. The substrate structure according to claim 1, further comprising:
at least one bonding layer disposed between the base and the at least one build-up structure layer; and
at least one third conductive through hole penetrating the at least one bonding layer and electrically connected to the at least one first conductive through hole and the at least one second conductive through hole.

3. The substrate structure according to claim 2, wherein a material of the at least one third conductive through hole comprises conductive paste, metal slurry, or nanowires.

4. The substrate structure according to claim 2, wherein in a cross-sectional view, the at least one first conductive through hole, the at least one second conductive through hole, and the at least one third conductive through hole have a same diameter.

5. The substrate structure according to claim 2, wherein in a cross-sectional view, the at least one first conductive through hole, the at least one second conductive through hole, and the at least one third conductive through hole are aligned with one another.

6. The substrate structure according to claim 1, wherein a material of the dielectric core plate of the base comprises an organic material, an inorganic material, or a non-conductive composite material.

7. The substrate structure according to claim 1, wherein a material of the dielectric layer of the at least one build-up structure layer comprises an organic material, an inorganic material, or a non-conductive composite material.

8. The substrate structure according to claim 1, wherein a material of the dielectric core plate of the base is the same as a material of the dielectric layer of the at least one build-up structure layer.

9. The substrate structure according to claim 1, wherein a Young's modulus of the at least one build-up structure layer is larger than a Young's modulus of the base.

10. The substrate structure according to claim 1, wherein a thickness of the base is between 80 micrometers and 800 micrometers.

11. The substrate structure according to claim 1, wherein a thickness of the at least one build-up structure layer is between 80 micrometers and 800 micrometers.

12. The substrate structure according to claim 1, wherein the base further comprises at least one first circuit pattern, the at least one build-up structure layer further comprises at least one second circuit pattern, the at least one first circuit pattern is electrically connected to the at least one first conductive through hole, and the at least one second circuit pattern is electrically connected to the at least one second conductive through hole.
